(19) United States
(12) Patent Application Publication
(10) Pub. No.: US 2011/0049631 A1
(43) Pub. Date: Mar. 3, 2011

(54) SEMICONDUCTOR INTEGRATED CIRCUIT HAVING INSULATED GATE FIELD EFFECT TRANSISTORS

(75) Inventor: Yasuhito Itaka, Saitama-ken (JP)

(73) Assignee: KABUSHIKI KAISHA TOSHIBA, Tokyo (JP)

(21) Appl. No.: 12/862,159

(22) Filed: Aug. 24, 2010

(30) Foreign Application Priority Data
Aug. 26, 2009 (JP) 2009195819

(51) Int. Cl. H01L 27/12; H01L 27/092

(52) U.S. Cl. 257/351; 257/391; 257/E27.112; 257/E27.067

(57) ABSTRACT

In one embodiment, a semiconductor integrated circuit is provided a first well region, a second well region, a first body bias supply unit and a second body bias supply unit. The first well region includes a first transistor having a first threshold voltage. The second well region includes a second transistor having an absolute value of a second threshold voltage higher than an absolute value of the first threshold voltage. The second well region is separated from the first well region. The second well region has the same conductive type as the first well region. The first body bias supply unit supplies a first body bias voltage to the first well region. The second body bias supply unit supplies a second body bias voltage to the second well region.

### CROSS REFERENCE TO RELATED APPLICATION

This application is based upon and claims the benefit of priority from the prior Japanese Patent Application No. 2009-195819, filed on Aug. 26, 2009, the entire contents of which are incorporated herein by reference.

### FIELD

Embodiments described herein relate generally to a semiconductor integrated circuit.

### BACKGROUND

With the advancement of miniaturization in semiconductor manufacturing technology, higher density and lower voltage have been achieved in LSIs. In order to reduce the voltage of a power supply of an LSI, it is necessary to reduce the threshold voltages of transistors. However, when the threshold voltages of the transistors are reduced, a subthreshold leak current increases.

An example of method to reduce the subthreshold leak current includes a multi-threshold voltage method. In the multi-threshold voltage method, the amount of implanted impurity ion is changed in transistor manufacturing process, so that transistors having different threshold voltages are used in accordance with the operating speed of a signal transmission path. In the multi-threshold voltage method, a dual threshold voltage method is often employed to appropriately use two types of transistors, i.e., a transistor having a low threshold voltage and a transistor having a high threshold voltage.

In the dual threshold voltage method, a slow transistor having a high threshold voltage is used for a path having sufficient margin in timing in order to reduce the subthreshold leak current, whereas a fast transistor having a low threshold voltage is used for a path with tight timing in order to satisfy a restriction imposed on timing. The fast transistor having the low threshold voltage has a larger subthreshold leak current. Japanese Patent Application Publication No. 2002-299454 discloses the dual threshold voltage method.

Another example of the method for reducing the subthreshold leak current includes a body bias method. In the body bias method, a source region and a body or well region of a transistor are separated, and the potential of the body or well region is changed with respect to the source potential.

The change in the potential causes back-gate bias effect, which varies the threshold voltage of the transistor. In normal operation, a body bias voltage is not applied, so that the threshold voltage is low. In standby state, a reverse body bias voltage is applied, so that the threshold voltage is high. Accordingly, the subthreshold leak current can be reduced in the standby state. Japanese Patent Application Publication No. 2006-19647 discloses the reduction of the subthreshold leak current.

With the body bias method, the operating speed of an LSI can be improved. In the case, a forward body bias voltage is applied when the subthreshold leak current is reduced. When the forward body bias voltage is applied, the threshold voltage drops, and the current flowing through the transistor increases, so that the operating speed of the LSI is improved. Japanese Patent Application Publication No. 2001-284535 discloses the application of the forward body bias voltage.

When an LSI is formed with a transistor having a low threshold voltage and a transistor having a high threshold voltage, which are formed by the dual threshold voltage method, and further the body bias method is employed to apply the forward body bias voltage to the LSI, the subthreshold leak current can be reduced in normal operation. On the other hand, the transistors can operate fast during fast operation.

However, a transistor having a low threshold voltage and a transistor having a high threshold voltage have different sensitivities in increasing the operating speeds in response to a forward body bias voltage. For example, when the supply voltage is 1.0 V, and a forward body bias voltage of 0.3 V is applied, the speed of an N-channel MOS transistor having a low threshold voltage improves by 10%, whereas the speed of an N-channel MOS transistor having a high threshold voltage improves by as much as about 20%.

Since a transistor having a high threshold voltage is used for a circuit which does not need to operate at a high speed, it is not necessary to increase the operating speed when a forward body bias voltage is applied. When the operating speed increases greatly, concerns arise that there may be problems of an increased subthreshold leak current and an insufficient hold time of a flip-flop.

In view of the entire operation of the LSI, it is necessary to uniformly improve both of the speed of a transistor having a low threshold voltage and the speed of a transistor having a high threshold voltage, when a forward body bias voltage is applied.

However, in the past, both of the transistor having the low threshold voltage and the transistor having the high threshold voltage are formed in the same substrate or in the same well region. Accordingly, there is a problem in that, when a forward body bias voltage is applied, the increase rate of the speed cannot be the same between the transistor having the low threshold voltage and the transistor having the high threshold voltage.

### BRIEF DESCRIPTION OF THE DRAWINGS

FIG. 1 is a schematic layout illustrating relationship between a provided body bias voltage and an arrangement of a well region of a semiconductor integrated circuit according to the first embodiment;

FIG. 2 is a schematic cross sectional view illustrating the semiconductor integrated circuit according to the first embodiment;

FIG. 3 is a schematic layout illustrating relationship between a provided body bias and an arrangement of a well region of a semiconductor integrated circuit according to the second embodiment;

FIG. 4 is a schematic cross sectional view illustrating the semiconductor integrated circuit according to the second embodiment;

FIG. 5 is a schematic layout illustrating relationship between a provided body bias voltage and an arrangement of a well region of a semiconductor integrated circuit according to the third embodiment; and

FIG. 6 is a schematic cross sectional view illustrating the semiconductor integrated circuit according to the third embodiment.

### DETAILED DESCRIPTION

In one embodiment, a semiconductor integrated circuit is provided a first well region, a second well region, a first body bias supply unit and a second body bias supply unit. The first well region includes a first transistor having a first threshold voltage. The second well region includes a second transistor having an absolute value of a second threshold voltage higher than an absolute value of the first threshold voltage. The second well region is separated from the first well region. The second well region has the same conductive type as the first well region. The first body bias supply unit supplies a first body bias voltage to the first well region. The second body bias supply unit supplies a second body bias voltage to the second well region.

In another embodiment, a semiconductor integrated circuit is provided a first N well region, a second N well region, a first P well region, a second P well region, a first body bias supply unit, a second body bias supply unit, a third body bias supply unit and a fourth body bias supply unit. The first N well region includes a first transistor having a first threshold voltage. The second N well region includes a second transistor having an absolute value of a second threshold voltage higher than an absolute value of the first threshold voltage. The second N well region is separated from the first N well region. The first P well region includes a third transistor having a third threshold voltage. The first P well region is separated from the first and second N well regions. The second P well region includes a fourth transistor having an absolute value of a fourth threshold voltage higher than an absolute value of the third threshold voltage. The second P well region is separated from the first N well region, the second N well region and the first P well region. The first body bias supply unit supplies a first body bias voltage to the first N well region. The second body bias supply unit supplies a second body bias voltage to the second N well region. The third body bias supply unit supplies a third body bias voltage to the first P well region. The fourth body bias supply unit supplies a fourth body bias voltage to the second P well region.

Further, multiple embodiments will be hereinafter described with reference to the drawings. In the drawings, the same reference numerals denote the same or similar portions.

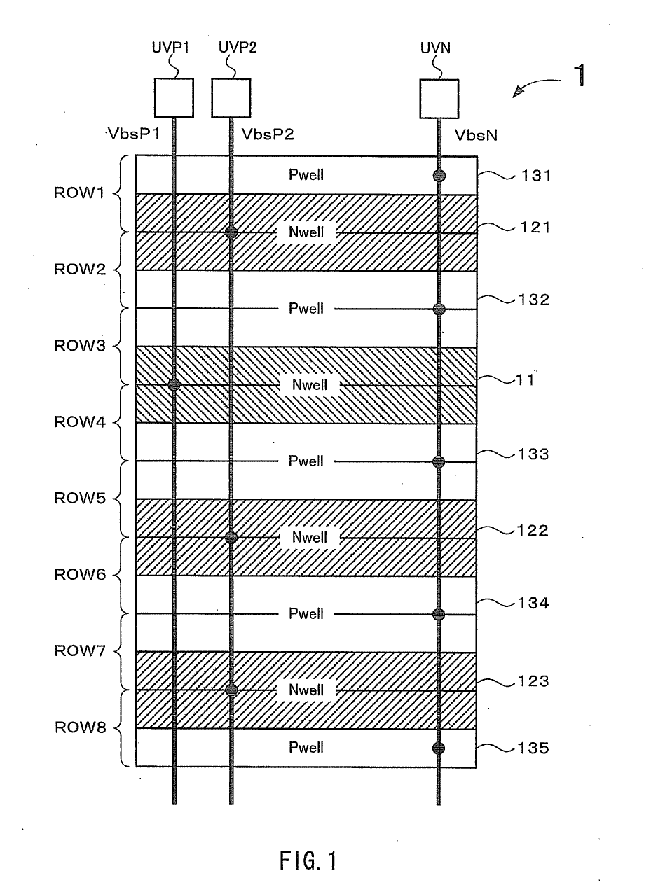

The first embodiment will be explained with reference to FIG. 1. FIG. 1 is a schematic layout illustrating relationship between a provided body bias voltage and an arrangement of a well region of a semiconductor integrated circuit according to the first embodiment.

As shown in FIG. 1, a semiconductor integrated circuit 1 is a CMOS LSI that is designed with the use of a previously prepared cell such as standard cell. The cell includes a cell in which transistors having a high threshold voltage are used to reduce the subthreshold leak current and a cell in which transistors having a low threshold voltage are used to increase the speed. In designing a layout, a cell constituted by transistors having the high threshold voltage and a cell constituted by transistors having the low threshold voltage are respectively arranged in different rows to constitute different cell rows.

In the example shown in FIG. 1, the cells including transistors having the high threshold voltage are arranged in ROW 1, ROW 2, ROW 5 to ROW 8, and the cells including transistors having the low threshold voltage are arranged in ROW 3 and ROW 4.

In accordance with the arrangement of the rows, P-well regions in which N-channel MOS transistors are formed and N-well regions in which P-channel MOS transistors are formed are alternately laid out.

A MOS transistor whose gate insulating film is made of silicon oxide film (SiO₂) is also called MOSFET. In the example, MOSFETs (metal oxide semiconductor field effect transistors) are used. Alternatively, the gate insulating film may be a MISFET (metal insulator semiconductor field effect transistor) formed with an insulating film other than silicon oxide film (SiO₂) or an insulating film partially including silicon oxide film (SiO₂). MOSFET and MISFET are also called IGFET (insulated gate field effect transistor).

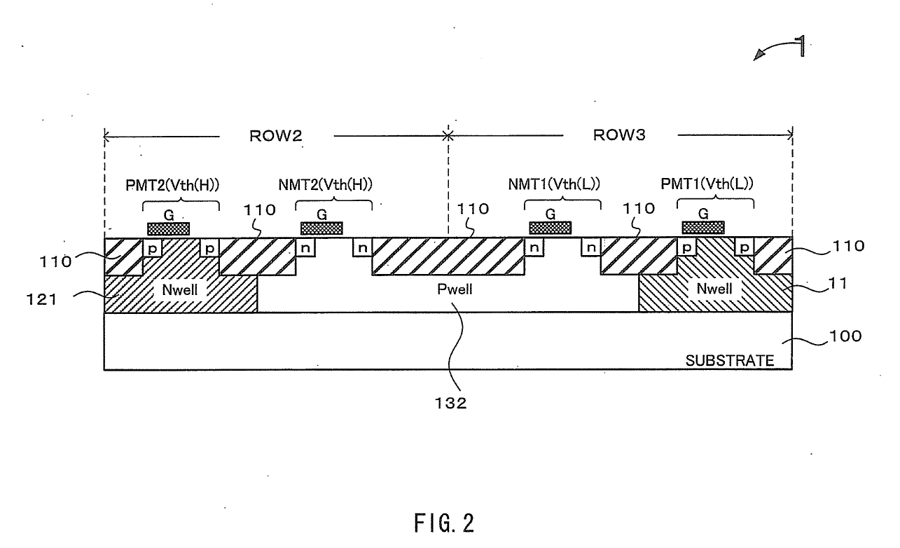

Subsequently, a structure of two rows arranged adjacent to each other will be explained with reference to FIG. 2. FIG. 2 is a schematic cross sectional view illustrating ROW 2 and ROW 3 shown in FIG. 1.

In FIG. 2, a P layer and an N layer, serving as a source region and a drain region of the MOS transistor, are formed in a P-type substrate 100. FIG. 2 shows that gate electrodes are formed on gate insulating films. Each transistor is separated by a device isolation insulating film 110.

As shown in FIG. 2, a P-channel MOS transistor PMT1 having a low threshold voltage arranged in ROW 3 is formed within an N well region 11 formed in the P-type substrate 100. A P-channel MOS transistor PMT2 having a high threshold voltage arranged in ROW 2 is formed within an N well region 121 formed in the P-type substrate 100. The threshold voltage of a P-channel MOS transistor is a minus (−) value, and therefore, the absolute value of a high threshold voltage is higher than the absolute value of a low threshold voltage.

A P well region 132 is arranged between the N well region 11 and the N well region 121. Since the N well region 11 and the N well region 121 are not electrically connected, a body bias can be independently applied to each of the N well region 11 and the N well region 121.

Each of a body bias of the P-channel MOS transistor PMT1 having the low threshold voltage arranged in ROW 3 and a body bias of the P-channel MOS transistor PMT2 having the high threshold voltage arranged in ROW 2 can be independently controlled.

On the other hand, an N-channel MOS transistor NMT1 having the low threshold voltage arranged in ROW 3 and an N-channel MOS transistor NMT2 having the high threshold voltage arranged in ROW 2 are formed within the same P well region 132. A body bias is commonly applied, via the P well region 132, to the N-channel MOS transistor NMT1 having the low threshold voltage and the N-channel MOS transistor NMT2 having the high threshold voltage.

Since the other P well regions 131, 133 to 135 shown in FIG. 1 are also formed in the P-type substrate 100 having the same conductivity type as the P well, the P well regions 131, 133 to 135 are connected to each other via the P-type substrate 100. Therefore, the body bias applied to all the N-channel MOS transistors is commonly controlled.

As described above, in the embodiment, the body bias to the P-channel MOS transistor PMT1 having the low threshold voltage and the body bias to the P-channel MOS transistor PMT2 having the high threshold voltage can be independently controlled.

The semiconductor integrated circuit 1 includes a body bias supply unit UVP1 and a body bias supply unit UVP2. The body bias supply unit UVP1 provides a body bias voltage VbsP1 to the N well region 11. The body bias voltage VbsP1 is given to the P-channel MOS transistors having the low threshold voltage. The body bias supply unit UVP2 provides a body bias voltage VbsP2 to the N well regions 121, 122, 123. The body bias voltage VbsP2 is given to the P-channel MOS transistors having the high threshold voltage.

A body bias voltage VbsN given to the N-channel MOS transistors is commonly provided by a body bias supply unit UVN to the P well regions 131 to 135.

In the embodiment, the body bias supply unit UVP1 and the body bias supply unit UVP2 can provide individually different body bias voltages to the P-channel MOS transistor PMT1 having the low threshold voltage and the P-channel MOS transistor PMT2 having the high threshold voltage. For example, when the operating speed of the P-channel MOS transistors are improved, forward body bias voltages can be individually given to the P-channel MOS transistor PMT1 having the low threshold voltage and the P-channel MOS transistor PMT2 having the high threshold voltage. As a result, the increase rate of the operating speed of the P-channel MOS transistor PMT1 having the low threshold voltage and the increase rate of the operating speed of the P-channel MOS transistor PMT2 having the high threshold voltage can be individually controlled.

Herein, a forward body bias voltage is as follows. In a case of a P-channel MOS transistor, the forward body bias voltage is a voltage lower than the voltage applied to the source (normally, the power supply voltage is applied). In a case of an N-channel MOS transistor, the forward body bias voltage is a voltage higher than the voltage applied to the source (normally, the ground potential is applied). When a forward body bias voltage is applied to a MOS transistor, the absolute value of the threshold voltage of the MOS transistor decreases.

On the other hand, a reverse body bias voltage is as follows. In a case of a P-channel MOS transistor, the reverse body bias voltage is a voltage higher than the voltage applied to the source (normally, the power supply voltage is applied). In a case of an N-channel MOS transistor, the reverse body bias voltage is a voltage lower than the voltage applied to the source (normally, the ground potential is applied). When a reverse body bias voltage is applied to a MOS transistor, the absolute value of the threshold voltage of the MOS transistor increases. When a reverse body bias voltage is applied, the subthreshold leak current of the MOS transistor is suppressed.

Subsequently explained is uses of the technique for individually controlling the increase rate of the operating speed of the P-channel MOS transistor PMT1 having the low threshold voltage and the increase rate of the operating speed of the P-channel MOS transistor PMT2 having the high threshold voltage. Herein, equalization of the increase rate of the operating speed, compensation for decrease of the operating speed during a low power supply voltage mode, and handling of operating frequency switching.

### 1. Equalization of the Increase Rate of the Operating Speed

A MOS transistor having a low threshold voltage and a MOS transistor having a high threshold voltage have different sensitivities in increasing the operating speeds in response to a forward body bias voltage. More specifically the MOS transistor having the high threshold voltage has a higher sensitivity in response to a forward body bias voltage. When the same forward bias voltage is applied to the MOS transistor having the high threshold voltage and the MOS transistor having the low threshold voltage, the increase rate of the operating speed of the MOS transistor having the high threshold voltage becomes more than the increase rate of the operating speed of the MOS transistor having the low threshold voltage. The increase rate of the operating speed of the transistor having the high threshold voltage used for a circuit that does not require high speed operation may be about the same as the increase rate of the operating speed of the MOS transistor having the low threshold voltage.

When the operation speed of the P-channel MOS transistor is improved, first, a forward body bias voltage of the P-channel MOS transistor PMT1 having the low threshold voltage is determined, and then a body bias voltage of the P-channel MOS transistor PMT2 having the high threshold voltage is determined in accordance with to the increase rate of the operating speed of the P-channel MOS transistor PMT1.

For example, the power supply voltage is set to Vdd, and the body bias voltage VbsP1 provided by the body bias supply unit UVP1 is set to a forward body bias voltage FBBP1=(Vdd−0.3V). At the occasion, the value of the forward body bias voltage of the body bias voltage VbsP2 provided from the body bias supply unit UVP2 is determined such that, when the increase rate of the operating speed of the P-channel MOS transistor PMT1 having the low threshold voltage is 10%, the increase rate of the operating speed of the P-channel MOS transistor PMT2 having the high threshold voltage attains 10%.

When the value of the forward body bias voltage of the body bias voltage VbsP2 is (Vdd−0.15V), a forward body bias voltage FBBP2 is determined to be (Vdd−0.15V) so as to be attained 10% at the increase rate of the operating speed of the P-channel MOS transistor PMT2 having the high threshold voltage.

When the forward body bias voltage FBBP1 of the transistor having the low threshold voltage and the forward body bias voltage FBBP2 of the transistor having the high threshold voltage are set as follows,

FBBP1=(Vdd−0.3V),

FBBP2=(Vdd−0.15V),

both of the increase rates of the operating speed of the P-channel MOS transistor PMT1 having the low threshold voltage and the increase rate of the operating speed of the P-channel MOS transistor PMT2 having the high threshold voltage attain 10%. Accordingly, a balance is achieved in the increase rate of the operating speed.

In the case, the forward body bias voltage FBBP2 of the P-channel MOS transistor PMT2 having the high threshold voltage can be kept to a low level, the subthreshold leak current of the P-channel MOS transistor PMT2 having the high threshold voltage is prevented from increasing.

Normally, a large number of P-channel MOS transistors having the high threshold voltage are used in one LSI with respect to the total number of transistors used in the LSI. Therefore, the increase in the subthreshold leak current of the P-channel MOS transistor having the high threshold voltage can be suppressed, and the effect of suppressing the increase in the subthreshold leak current of the entire LSI can be enhanced.

### 2. Compensation for Decrease of the Operating Speed During a Low Power Supply Voltage Mode

In a transitional state from the normal operation to the standby operation, the power supply voltage may be switched to reduce the power consumption, and the mode may be switched to a low power supply voltage mode in which the voltage of the power supply is reduced.

When the voltage of the power supply is decreased, the operating speed of the P-channel MOS transistor PMT2 having the high threshold voltage decreases more greatly than the operating speed of the P-channel MOS transistor PMT1 having the low threshold voltage.

Accordingly, in the case, the forward body bias voltage FBBP2 of the P-channel MOS transistor PMT2 having the high threshold voltage is set high to compensate the decrease of the operating speed of the P-channel MOS transistor PMT2 having the high threshold voltage.

For example, when the power supply voltage is normal Vdd, the forward body bias voltages FBBP1 of the transistor having the low threshold voltage and the forward body bias voltage FBBP2 of the transistor having the high threshold voltage are for example set as follows,

FBBP1=(Vdd−0.3V),

FBBP2=(Vdd−0.15V).

The setting achieves a balance between the increase rate of the operating speed of the P-channel MOS transistor PMT2 having the high threshold voltage and the increase rate of the operating speed of the P-channel MOS transistor PMT1 having the low threshold voltage. In contrast, when the power supply voltage is Vdd1 which is less than Vdd, the forward body bias voltages FBBP1 of the transistor having the low threshold voltage and the forward body bias voltage FBBP2 of the transistor having the high threshold voltage are set as follows,

FBBP11=(Vdd1−0.3V),

FBBP22=(Vdd1−0.3V).

The setting compensates the decrease of the operating speed of the P-channel MOS transistor PMT2 having the high threshold voltage, and can maintain a balance between the increase rate of the operating speed of the P-channel MOS transistor PMT2 having the high threshold voltage and the increase rate of the operating speed of the P-channel MOS transistor PMT1 having the low threshold voltage.

### 3. Handling of Operating Frequency Switching

When the operating frequency is switched so that the operating clock frequency is increased in a case where fast processing is required and the operating clock frequency is decreased in a case of slow processing, the power supply voltage is switched in accordance with the switching of the operating frequency, for example. In other words, the switching is performed so that the power supply voltage is increased when the operating frequency is high and the power supply voltage is decreased when the operating frequency is low.

In the case, when power supply voltage is decreased, the operating speed of the P-channel MOS transistor PMT2 having the high threshold voltage decreases more greatly. Accordingly, the forward body bias voltage of the P-channel MOS transistor PMT2 having the high threshold voltage is increased to compensate the decrease of the operating speed of the P-channel MOS transistor PMT2 having the high threshold voltage.

In accordance with the embodiment as described above, the P-channel MOS transistor PMT1 having the low threshold voltage and the P-channel MOS transistor PMT2 having the high threshold voltage can individually give the forward body bias voltages. Therefore, the increase rate of the operating speed of the P-channel MOS transistor PMT1 having the low threshold voltage and the increase rate of the operating speed of the P-channel MOS transistor PMT2 having the high threshold voltage can be made almost the same. In the case, the forward body bias voltage applied to the P-channel MOS transistor PMT2 having the high threshold voltage can be reduced, and the increase in the subthreshold leak current of the P-channel MOS transistor PMT2 having the high threshold voltage can be suppressed.

When the power supply voltage is decreased, the decrease in the speed of the P-channel MOS transistor PMT2 having the high threshold voltage can be compensated by setting the forward body bias voltage applied to the P-channel MOS transistor PMT2 having the high threshold voltage. Therefore, even when the power supply voltage is decreased, the increase rate of the operating speed of the P-channel MOS transistor PMT2 having the high threshold voltage and the increase rate of the operating speed of the P-channel MOS transistor PMT1 having the low threshold voltage can be made almost the same.

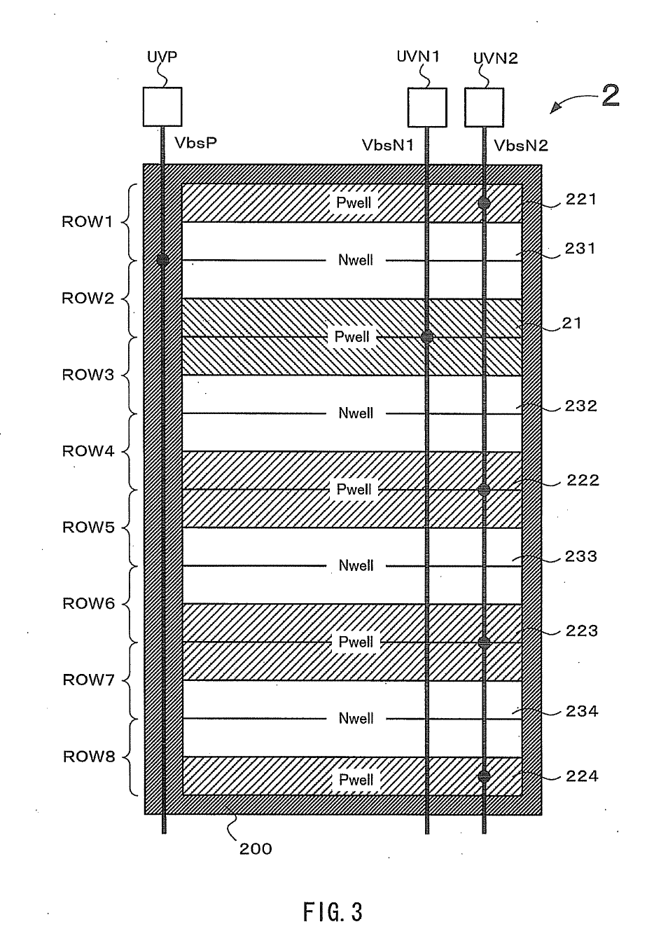

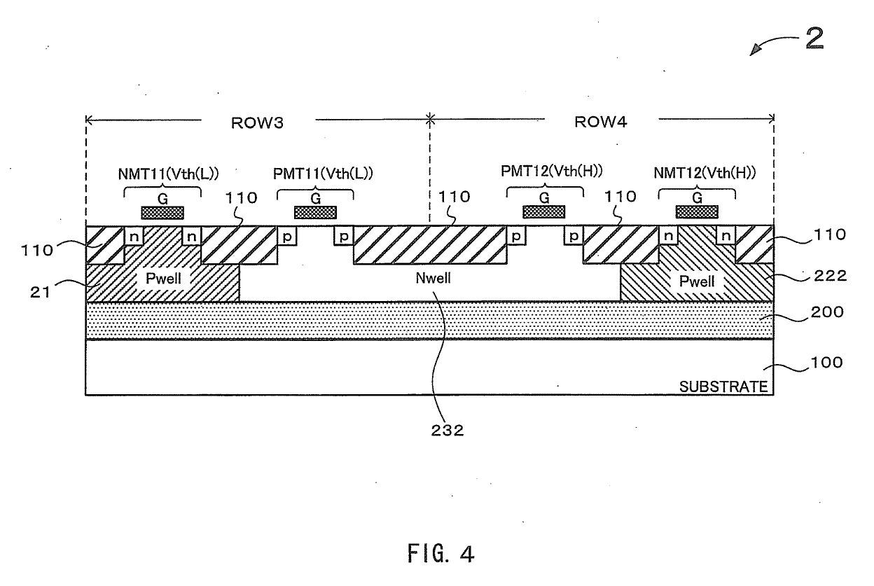

The second embodiment will be explained with reference to FIG. 3 and FIG. 4. FIG. 3 is a schematic layout illustrating relationship between a provided body bias and an arrangement of a well region of a semiconductor integrated circuit. FIG. 4 is a schematic cross sectional view illustrating ROW 3 and ROW 4 shown in FIG. 3. In the first embodiment, the body bias voltage of the P-channel MOS transistor is controlled in accordance with the threshold voltage. In the embodiment, the body bias voltage of the N-channel MOS transistor is controlled in accordance with the threshold voltage.

As shown in FIG. 3, in a semiconductor integrated circuit 2, the cells including transistors having the high threshold voltage are arranged in ROW 1, ROW 4 to ROW 8, and the cells including transistors having the low threshold voltage are arranged in ROW 2 and ROW 3.

As shown in FIG. 4, the semiconductor integrated circuit 2 is different from the first embodiment in that a deep N well region 200 is formed in a P-type substrate 100. Well regions such as a P well region 21, a P well region 222, and an N well region 232 are formed in the deep N well region 200.

In the embodiment, the N well region is arranged between the P well regions. The P well regions are not electrically connected to each other. In contrast, the N well regions are the same conductive type as the deep N well region 200, and are electrically connected to each other via the deep N well region 200.

The semiconductor integrated circuit 2 includes a body bias supply unit UVN1 and a body bias supply unit UVN2. As shown in FIG. 3, the body bias supply unit UVN1 provides a body bias voltage VbsN1 to the P well region 21. The body bias voltage VbsN1 is applied to the N-channel MOS transistors having the low threshold voltage. The body bias supply unit UVN2 provides a body bias voltage VbsN2 to the P well regions 221 to 224. The body bias voltage VbsN2 is applied to the N-channel MOS transistors having the high threshold voltage.

The body bias supply unit UVP commonly provides a body bias voltage VbsP applied to the P-channel MOS transistors to the N well regions 231 to 234 via the deep N well region 200.

In the embodiment, the body bias supply unit UVN1 and the body bias supply unit UVN2 individually provide forward body bias voltages to an N-channel MOS transistor NMT1 having the low threshold voltage and an N-channel MOS transistor NMT2 having the low threshold voltage.

For example, when the increase rates of the operating speeds are equalized, the power supply voltage is set to Vdd, and the ground potential is set to 0 (zero) V. In addition, a body bias voltage VbsN1 supplied from the body bias supply unit UVN1 is set such that a forward body bias voltage FBBN1=(0.3V). At the occasion, the value of the forward body bias voltage of the body bias voltage VbsN2 provided from the body bias supply unit UVN2 is determined such that, when the increase rate of the operating speed of the N-channel MOS transistor NMT1 having the low threshold voltage is 10%, the increase rate of the operating speed of the N-channel MOS transistor NMT2 having the high threshold voltage attains 10%.

When the value of the forward body bias voltage of the body bias voltage VbsN2 is (0.15V), a forward body bias voltage FBBN2=(0.15V) so as to be attained 10% at the increase rate of the operating speed of the N-channel MOS transistor NMT2 having the high threshold voltage.

When the forward body bias voltage FBBN1 of the transistor having the low threshold voltage and the forward body bias voltage FBBN2 the transistor having the high threshold voltage are set as follows,

FBBN1=(0.3V),

FBBN2=(0.15V),

both of the increase rates of the operating speed of the N-channel MOS transistor NMT1 having the low threshold voltage and the increase rate of the operating speed of the N-channel MOS transistor NMT2 having the high threshold voltage attain 10%. Accordingly, the balance is achieved in the increase rate of the operating speed.

As a result, the increase rate of the operating speed of the N-channel MOS transistor NMT1 having the low threshold voltage and the increase rate of the operating speed of the N-channel MOS transistor NMT2 having the high threshold voltage can be individually controlled.

The compensation for decrease of the operating speed during the low power supply voltage mode and the handling of operating frequency switching are the same as those of the first embodiment, and the description thereabout is omitted.

In accordance with the embodiment as described above, the forward body bias voltages can be individually given to the N-channel MOS transistors having different threshold voltages, and the increase rate of the operating speed of the N-channel MOS transistor NMT1 having the low threshold voltage and the increase rate of the operating speed of the N-channel MOS transistor NMT2 having the high threshold voltage can be individually controlled.

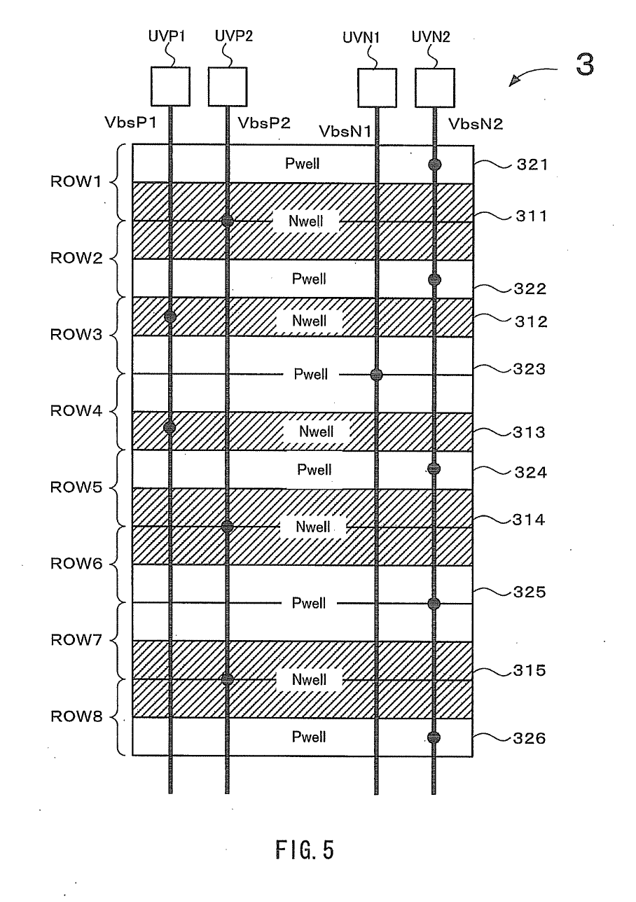

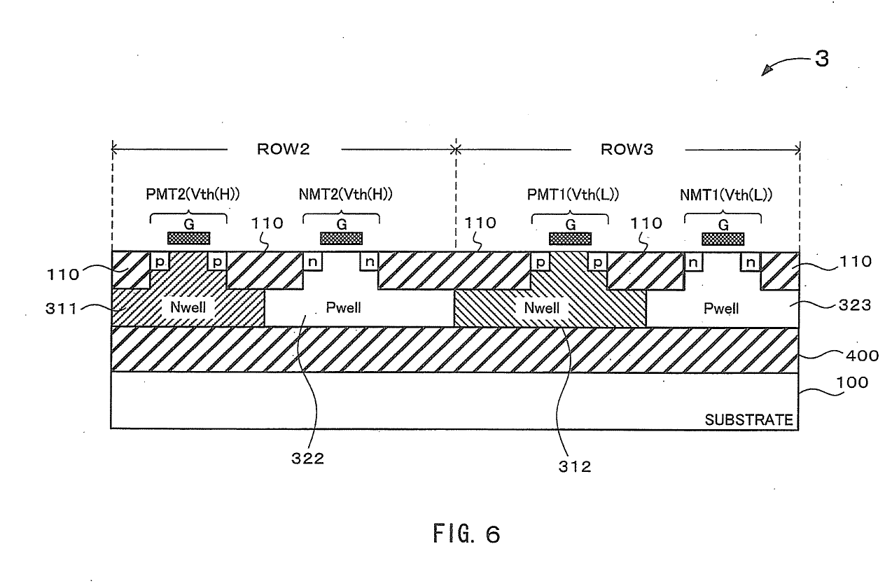

The third embodiment will be explained with reference to FIG. 5 and FIG. 6. FIG. 5 is a schematic layout illustrating relationship between a provided body bias voltage and an arrangement of a well region of a semiconductor integrated circuit. FIG. 6 is a schematic cross sectional view illustrating ROW2 and ROW3 shown in FIG. 5. In the first embodiment, the body bias voltage of the P-channel MOS transistor is controlled in accordance with the threshold voltage. In the second embodiment, the body bias voltage of the N-channel MOS transistor is controlled in accordance with the threshold voltage. In contrast, in the embodiment, the body bias voltage of the P-channel MOS transistor and the body bias voltage of the N-channel MOS transistor are respectively controlled in accordance with the threshold voltage.

As shown in FIG. 5, in a semiconductor integrated circuit 3, the cells including transistors having the high threshold voltage are arranged in ROW 1, ROW 2, ROW 5 to ROW 8, and the cells including transistors having the low threshold voltage are arranged in ROW 3 and ROW 4.

As shown in FIG. 6, the semiconductor integrated circuit 3 is different from the first embodiment in that a BOX layer 400 is formed on a P-type substrate 100. The BOX layer is a buried oxide layer. Well regions such as a P well region 322, a P well region 223, an N well region 311, an N well region 312, and the like are formed on the BOX layer 400. The BOX layer 400 electrically separates between the P well regions and the P-type substrate 100 and between the N well regions and the P-type substrate 100. The P-type substrate 100 and the BOX layer 400 are used as SOI substrates. The SOI substrate is a silicon-on-insulator substrate.

In the embodiment, the N well region is arranged between the P well regions. The P well regions are not electrically connected to each other. The P well region is arranged between the N well regions. The N well regions are not electrically connected to each other.

The semiconductor integrated circuit 3 includes a body bias supply unit UVP1, a body bias supply unit UVP2, a body bias supply unit UVN1, and a body bias supply unit UVN2. As shown in FIG. 5, the body bias supply unit UVP1 provides a body bias voltage VbsP1 to the N well region 312 and the N well region 313. The body bias voltage VbsP1 is applied to the P-channel MOS transistors having the low threshold voltage. The body bias supply unit UVP2 provides a body bias voltage VbsP2 to the N well region 311, the N well region 314, and the N well region 315. The body bias voltage VbsP2 is applied to the P-channel MOS transistors having the high threshold voltage. The body bias supply unit UVN1 provides a body bias voltage VbsN1 to the P well region 323. The body bias voltage VbsN1 is applied to the N-channel MOS transistors having the low threshold voltage. The body bias supply unit UVN2 provides a body bias voltage VbsN2 to the P well region 321, the P well region 322, the P well regions 324 to 226. The body bias voltage VbsN2 is applied to the N-channel MOS transistors having the high threshold voltage.

In the embodiment, the body bias supply unit UVP1 and the body bias supply unit UVP2 individually give forward body bias voltages to the P-channel MOS transistor PMT1 having the low threshold voltage and the P-channel MOS transistor PMT2 having the high threshold voltage. Further, the body bias supply unit UVN1 and the body bias supply unit UVN2 individually give forward body bias voltages to an N-channel MOS transistor NMT1 having the low threshold voltage and an N-channel MOS transistor NMT2 having the low threshold voltage.

For example, when the increase rates of the operating speeds are equalized, the power supply voltage is set to Vdd, and a body bias voltage VbsP1 supplied from the body bias supply unit UVP1 is set such that a forward body bias voltage FBBP1=(Vdd−0.3V). At the occasion, the value of the forward body bias voltage of the body bias voltage VbsP2 provided from the body bias supply unit UVP2 is determined such that, when the increase rate of the operating speed of the P-channel MOS transistor PMT1 having the low threshold voltage is 10%, the increase rate of the operating speed of the P-channel MOS transistor PMT2 having the high threshold voltage attains 10%. Further, for example, the ground potential is set to 0 (zero) V, and a body bias voltage VbsN1 supplied from the body bias supply unit UVN1 is set such that a forward body bias voltage FBBN1=(0.3V). At the occasion, the value of the forward body bias voltage of the body bias voltage VbsN2 provided from the body bias supply unit UVN2 is determined such that, when the increase rate of the operating speed of the N-channel MOS transistor NMT1 having the low threshold voltage is 10%, the increase rate of the operating speed of the N-channel MOS transistor NMT2 having the high threshold voltage attains 10%.

When the value of the forward body bias voltage of the body bias voltage VbsP2 is (Vdd−0.15V), a forward body bias voltage FBBP2=(Vdd−0.15V). Further, when the value of the forward body bias voltage of the body bias voltage VbsN2 is (0.15V), a forward body bias voltage FBBN2=(0.15V).

With the above setting, both of the increase rates of the operating speed of the P-channel MOS transistor PMT1 having the low threshold voltage and the increase rate of the operating speed of the P-channel MOS transistor PMT2 having the high threshold voltage attain 10%. Accordingly, a balance is achieved in the increase rate of the operating speed. Further, both of the increase rates of the operating speed of the N-channel MOS transistor NMT1 having the low threshold voltage and the increase rate of the operating speed of the N-channel MOS transistor NMT2 having the high threshold voltage attain 10%. Accordingly, the balance is achieved in the increase rate of the operating speed.

The increase rate of the operating speed of the P-channel MOS transistor PMT1 and the N-channel MOS transistor NMT1 having the low threshold voltage and the increase rate of the operating speed of the P-channel MOS transistor PMT2 and the N-channel MOS transistor NMT2 having the high threshold voltage can be individually controlled. As a result, the increase rate of the operating speed of an inverter, a logic gate, and a buffer constituted by the P-channel MOS transistor PMT1 and the N-channel MOS transistor NMT1 having the low threshold voltage and the increase rate of the operating speed of a combinational logic and a buffer constituted by the P-channel MOS transistor PMT2 and the N-channel MOS transistor NMT2 having the high threshold voltage can be set to the same value. As described above, it should be noted that the forward body bias voltage technology can be applied not only to the combinational logic and the buffer but also to a sequential logic. Examples of the combinational logic include a logic gate, a multiplexer, an adder, a multiplier, and the like. Examples of the sequential logic include a flip-flop, a counter, and the like.

The compensation for decrease of the operating speed during the low power supply voltage mode and the handling of operating frequency switching are the same as those of the first embodiment and the second embodiment, and the description thereabout is omitted.

In accordance with the embodiment as described above, the forward body bias voltages can be individually given to the P-channel MOS transistors and the N-channel MOS transistors having different threshold voltages, and the increase rate of the operating speed of the P-channel MOS transistor PMT1 having the low threshold voltage and the increase rate of the operating speed of the P-channel MOS transistor PMT2 having the high threshold voltage can be individually controlled. Further, the increase rate of the operating speed of the N-channel MOS transistor NMT1 having the low threshold voltage and the increase rate of the operating speed of the N-channel MOS transistor NMT2 having the high threshold voltage can be individually controlled. Therefore, even when the threshold voltages are different, the increase rates of the operating speeds of the inverter, the logic gate, and the buffer can be set to the same value.

In the third embodiment, the N well regions and the P well regions are respectively separated by the BOX layer. Alternatively, a triple well structure may be used to respectively separate the N well regions and the P well regions, for example.

Further, the invention can also be applied to a case where there are three or more threshold voltages. In such case, for example, when the increase rates of the operating speeds are equalized, body bias voltages of the transistors may be adjusted for each of threshold voltages higher than the lowest threshold voltage, in accordance with the body bias voltage of the transistor having the lowest threshold voltage.

While certain embodiments have been described, the embodiments have been presented by way of example only, and are not intended to limit the scope of the inventions. Indeed, the semiconductor integrated circuits described herein may be embodied in a variety of other forms; furthermore, various omissions, substitutions and changes in the form of the semiconductor integrated circuits described herein may be made without departing from the spirit of the inventions. The accompanying claims and their equivalents are intended to cover such forms or modifications as would fall within the scope and spirit of the inventions.

What is claimed is:

1. A semiconductor integrated circuit, comprising:
a first well region including a first transistor having a first threshold voltage;
a second well region including a second transistor having an absolute value of a second threshold voltage higher than an absolute value of the first threshold voltage, the second well region being separated from the first well region, the second well region having the same conductive type as the first well region;
a first body bias supply unit to supply a first body bias voltage to the first well region; and
a second body bias supply unit to supply a second body bias voltage to the second well region.

2. The semiconductor integrated circuit according to claim 1, wherein the first body bias voltage is a first forward body bias voltage, and wherein the second body bias voltage is a second forward body bias voltage, and wherein the second forward body bias voltage is adjusted to a voltage corresponding to the first forward body bias voltage.

3. The semiconductor integrated circuit according to claim 2, wherein the first forward body bias voltage is adjusted when a supply voltage is switched.

4. The semiconductor integrated circuit according to claim 3, wherein switching of the supply voltage is performed when an operating frequency is switched.

5. The semiconductor integrated circuit according to claim 1, wherein the first and second well regions include a cell row arranged a plurality of cells, respectively, and wherein a plurality of cells composed of a cell row include transistors having one and the same threshold voltage, respectively.

6. The semiconductor integrated circuit according to claim 1, wherein the first and second well regions are a N well region, and wherein the first and second transistors are a P-channel MOSFET or a P-channel MISFET.

7. The semiconductor integrated circuit according to claim 1, wherein the first and second well regions are a P well region, and wherein the first and second transistors are a N-channel MOSFET or a N-channel MISFET.

8. The semiconductor integrated circuit according to claim 1, further comprising:
a third well region including a third transistor having an absolute value of a third threshold voltage higher than an absolute value of the second threshold voltage, the third well region being separated from the first and second well regions, the third well region having the same conductive type as the first well region; and
a third body bias supply unit to supply a third body bias voltage to the third well region.

9. The semiconductor integrated circuit according to claim 8, wherein the first body bias voltage is a first forward body bias voltage, and wherein the second body bias voltage is a second forward body bias voltage, and wherein the third body bias voltage is a third forward body bias voltage, and wherein the second and third forward body bias voltages are adjusted to a voltage corresponding to the first forward body bias voltage.

10. A semiconductor integrated circuit, comprising:
a first N well region including a first transistor having a first threshold voltage;
a second N well region including a second transistor having an absolute value of a second threshold voltage higher than an absolute value of the first threshold voltage, the second N well region being separated from the first N well region;
a first P well region including a third transistor having a third threshold voltage, the first P well region being separated from the first and second N well regions;
a second P well region including a fourth transistor having an absolute value of a fourth threshold voltage higher than an absolute value of the third threshold voltage, the second P well region being separated from the first N well region, the second N well region and the first P well region;
a first body bias supply unit to supply a first body bias voltage to the first N well region;
a second body bias supply unit to supply a second body bias voltage to the second N well region;
a third body bias supply unit to supply a third body bias voltage to the first P well region; and
a fourth body bias supply unit to supply a fourth body bias voltage to the second P well region.

11. The semiconductor integrated circuit according to claim 10, wherein the first body bias voltage is a first forward body bias voltage, and wherein the second body bias voltage is a second forward body bias voltage, and wherein the third body bias voltage is a third forward body bias voltage, and wherein the fourth body bias voltage is a fourth forward body bias voltage, and wherein the second forward body bias voltage is adjusted to a voltage corresponding to the first forward body bias voltage, and wherein the fourth forward body bias voltage is adjusted to a voltage corresponding to the third forward body bias voltage.

12. The semiconductor integrated circuit according to claim 11, wherein the first and third forward body bias voltages are adjusted when a supply voltage is switched.

13. The semiconductor integrated circuit according to claim 12, wherein switching of the supply voltage is performed when an operating frequency is switched.

14. The semiconductor integrated circuit according to claim 10, wherein the first N well region and the first P well region are adjacent to each other, and wherein the second N well region and the second P well region are adjacent to each other.

15. The semiconductor integrated circuit according to claim 10, wherein the first and second transistors are a P-channel MOSFET or a P-channel MISFET, and wherein the third and fourth transistors are a N-channel MOSFET or a N-channel MISFET.

16. The semiconductor integrated circuit according to claim 10, wherein a BOX layer is formed directly below the first N well region, the second N well region, the first P well region and the second P well region.

17. The semiconductor integrated circuit according to claim 10, wherein a combinational logic, a buffer and a sequential logic are composed of the first and third transistors, and wherein a combinational logic, a buffer and a sequential logic are composed of the second and fourth transistors.
